(19) United States
(12) Patent Application Publication
(10) Pub. No.: US 2024/0331986 A1
(43) Pub. Date: Oct. 3, 2024

(54) PLASMA ETCHING APPARATUS AND PLASMA ETCHING METHOD

(71) Applicant: Tokyo Electron Limited, Tokyo (JP)

(72) Inventor: Yasunobu SUZUKI, Nirasaki City (JP)

(21) Appl. No.: 18/616,526

(22) Filed: Mar. 26, 2024

(30) Foreign Application Priority Data
Mar. 28, 2023 (JP) 2023-050912

(51) Int. Cl. H01J 37/32; H01L 21/3065

(52) U.S. Cl. CPC H01J 37/32715; H01L 21/3065; H01J 2237/20207; H01J 2237/334

(57) ABSTRACT

A plasma etching apparatus includes: a chamber, a support body provided inside the chamber to hold a substrate, a plasma generator provided with a plasma source to generate plasma, and a controller. The support body has a placement surface on which the substrate is placed, rotates the substrate about a perpendicular line passing through a center of the substrate, and is configured such that the placement surface is tilted with respect to a horizontal plane and the perpendicular line passes through a center of the plasma source only when the placement surface is not tilted with respect to the horizontal plane. The controller performs control so that during plasma etching, the placement surface is tilted with respect to the horizontal plane and the substrate is rotated about the perpendicular line, and control so that a total number of rotations of the substrate about the perpendicular line becomes a predetermined value.

### CROSS-REFERENCE TO RELATED APPLICATION

This application is based upon and claims the benefit of priority from Japanese Patent Application No. 2023-050912, filed on Mar. 28, 2023, the entire contents of which are incorporated herein by reference.

### TECHNICAL FIELD

The present disclosure relates to a plasma etching apparatus and a plasma etching method.

### BACKGROUND

Patent Document 1 discloses a plasma processing apparatus for a substrate, which includes a plasma generator configured to generate plasma inside a processing container, and a support body configured to place the substrate on a tilted placement surface and rotatably support the substrate inside the processing container.

### PRIOR ART DOCUMENT

### Patent Document

Patent Document 1: Japanese Laid-Open Patent Publication No. 2021-052170

### SUMMARY

According to an embodiment of the present disclosure, a plasma etching apparatus includes: a chamber; a support body provided inside the chamber and configured to hold a substrate; a plasma generator including a plasma source and configured to generate plasma inside the chamber; and a controller, wherein the support body has a placement surface on which the substrate is placed, and is configured to rotate the substrate about a perpendicular line passing through a center of an upper surface of the substrate placed on the placement surface, and the support body is configured such that the placement surface is tilted with respect to a horizontal plane, the perpendicular line passes through a center of the plasma source only when the placement surface is not tilted with respect to the horizontal plane, and the controller performs a first control so that during a plasma etching, the placement surface is tilted with respect to the horizontal plane and the substrate placed on the placement surface is rotated about the perpendicular line, and a second control so that a total number of the rotations of the substrate placed on the placement surface about the perpendicular line during the plasma etching becomes a predetermined value.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross-sectional view schematically showing an example of a tiltable pre-cleaning apparatus as a plasma etching apparatus according to the present embodiment.

FIG. 2 is a diagram for explaining an example of a support body.

FIG. 3 is a diagram showing an example of an internal structure of a container.

FIG. 4 is a diagram showing an example of a plasma density distribution on an upper surface of a semiconductor wafer placed on a placement surface.

FIG. 5 is a diagram showing an example of an orientation of a semiconductor wafer at the time of starting plasma etching.

FIG. 6 is a diagram showing an example of the orientation of the semiconductor wafer at the time of starting the plasma etching.

FIG. 7 is a diagram for explaining another example of a total number of rotations of a wafer W during the plasma etching.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a process of manufacturing a semiconductor device or the like, a plasma-based etching, that is, plasma etching, is sometimes performed on a substrate such as a semiconductor wafer (hereinafter referred to as “wafer”). The plasma etching is performed in a state in which the substrate is supported by a substrate support body provided inside a depressurized processing chamber.

The substrate support body may be configured to be tiltable, and an upper surface of the substrate supported by the substrate support body, that is, a target surface to be processed may be tilted with respect to a horizontal plane during the plasma etching (that is, the target surface to be processed may not be parallel to the horizontal plane). With this configuration, when the target surface to be processed is not tilted, a perpendicular line passing through a center of the target surface to be processed passes through a center of a plasma source. However, when the target surface to be processed is tilted, the perpendicular line passing through the center of the target surface to be processed does not pass through the center of the plasma source.

Further, when the target surface to be processed is tilted as described above during the plasma etching, the substrate supported by the substrate support body may be rotated about the perpendicular line passing through the center of the target surface to be processed during the plasma etching in order to improve an in-plane uniformity of etching results.

For example, the plasma etching is terminated after a predetermined period of processing time has elapsed from the start of the plasma etching. In this case, when the target surface to be processed is tilted and the substrate is rotated during the plasma etching as described above, an orientation of the substrate on the substrate support body may differ between the start and end of the plasma etching. When the orientation of the substrate on the substrate support body is different at the start and end of the plasma etching as described above, the in-plane uniformity of plasma-based etching results may be deteriorated. This point is remarkable when a required etching amount is on the order of several nanometers, that is, 5 nm or less. This is because the processing time of the plasma etching is short and the total number of rotations of the substrate during the plasma etching is small.

Therefore, the technique according to the present disclosure improves a substrate in-plane uniformity of plasma-based etching results.

Hereinafter, a plasma etching apparatus and a plasma etching method according to the present embodiment will be described with reference to the drawings. Throughout the specification and drawings, elements having substantially the same functional configuration will be designated by like reference numerals and duplicate descriptions thereof will be omitted.

### <Tiltable Pre-Cleaning Apparatus>

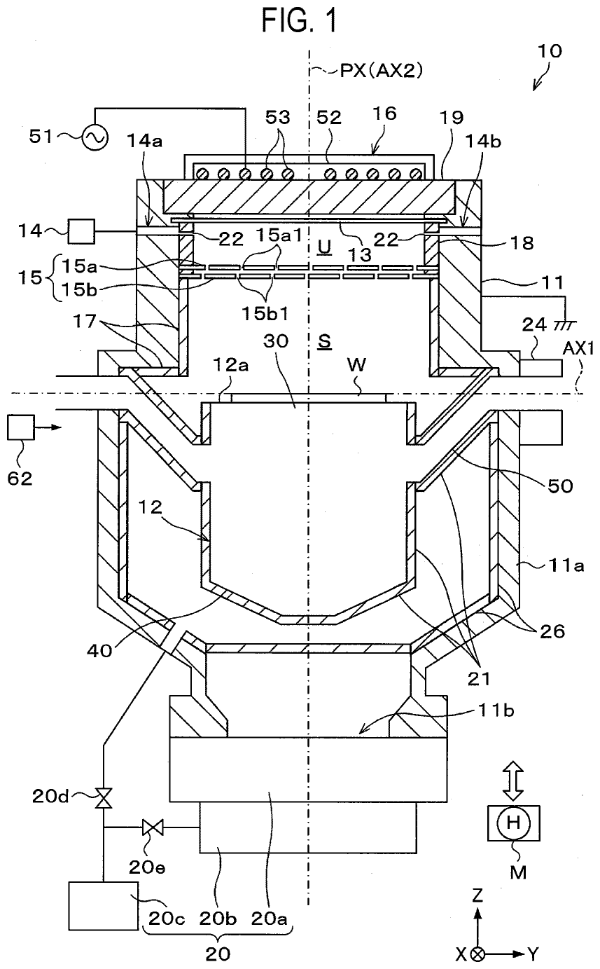

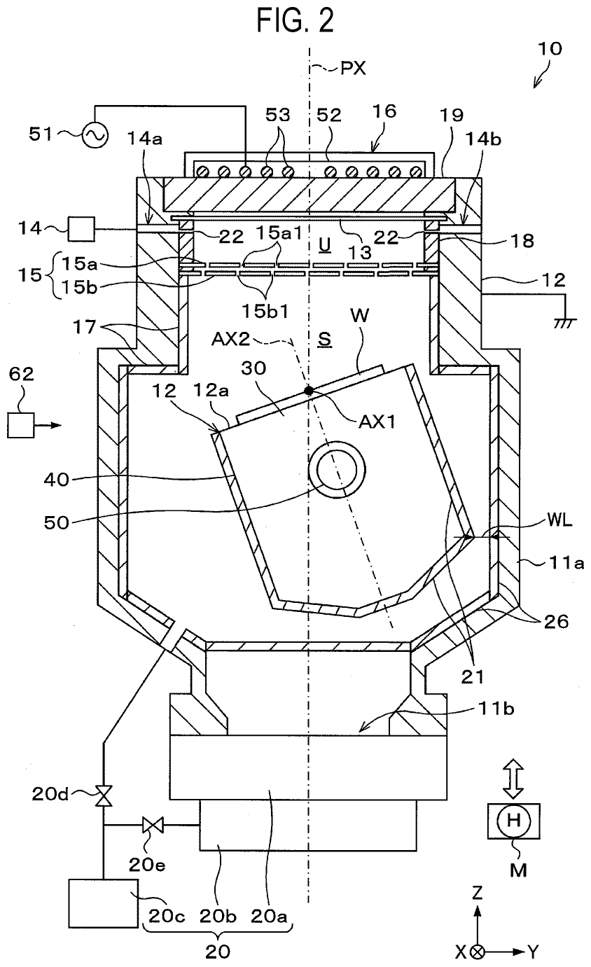

FIG. 1 is a cross-sectional view schematically showing an example of a tiltable pre-cleaning apparatus 10 as a plasma etching apparatus according to the present embodiment. FIG. 2 is a diagram for explaining an example of a support body, which will be described later. FIGS. 1 and 2 show the tiltable pre-cleaning apparatus 10 with a processing container 11 (to be described later) cut away in one plane including an axial line PX extending in a vertical direction.

The tiltable pre-cleaning apparatus 10 is an example of a plasma etching apparatus that performs, a plasma-based etching, that is, plasma etching, on a wafer W as a substrate. In addition, the tiltable pre-cleaning apparatus 10 may be used to remove an oxide on the wafer W between formation of one film and formation of a subsequent film, or may be used to make thin and planarize a formed film.

As shown in FIGS. 1 and 2, the tiltable pre-cleaning apparatus 10 includes the processing container 11, a support body 12, a gas supplier 14, an ICP (Inductively Coupled Plasma) source unit 16 as a plasma source, an exhaust system 20, a bias power supplier 62, and a controller M.

The processing container 11 has a substantially cylindrical shape and is made of aluminum. In one embodiment, a central axial line of the processing container 11 coincides with the axial line PX. The processing container 11 provides a processing space S in which the plasma etching is performed on the wafer W.

The processing container 11 has, for example, a substantially constant width in a middle portion 11a in a height direction, that is, in a portion in which the support body 12 is accommodated. Further, the processing container 11 has a tapered shape whose width gradually narrows from a lower end of the middle portion 11a toward a bottom portion of the processing container 11. In addition, the bottom portion of the processing container 11 has an exhaust port 11b formed therein. The exhaust port 11b is formed in an axial symmetrical relationship with the axial line PX.

The support body 12 is provided inside the processing container 11. The support body 12 has an upper surface 12a (hereinafter referred to as a placement surface 12a) on which the wafer W is placed. The support body 12 attracts and holds the wafer W on the placement surface 12a using an electrostatic chuck 31.

Further, the support body 12 is configured to be tiltable. Specifically, the support body 12 is configured such that the placement surface 12a is tilted with respect to a horizontal plane. More specifically, the support body 12 is configured to be rotatable about a first axial line AX1 orthogonal to the axial line PX. The support body 12 may be tilted with respect to the axial line PX with rotation of a tilted shaft portion 50 about the first axial line AX1. In one embodiment, a height of the first axial line AX1 is the same as a height of the wafer W on the placement surface 12a (specifically, a height of the upper surface of the wafer W) when the support body 12 is not tilted.

The tiltable pre-cleaning apparatus 10 includes a driver 24 to tilt the support body 12. The driver 24 is provided outside the processing container 11 to generate a drive force for rotating the support body 12 about the first axial line AX1. FIG. 1 shows the tiltable pre-cleaning apparatus 10 with the support body 12 not tilted, and FIG. 2 shows the tiltable pre-cleaning apparatus 10 with the support body 12 tilted.

Further, the support body 12 rotatably supports the wafer W. Specifically, the support body 12 is configured to be able to rotate the wafer W about a perpendicular line passing through the center of the wafer W placed on the placement surface 12a (specifically, the center of the placement surface 12a). More specifically, the support body 12 is configured to be able to rotate the wafer W placed on the placement surface 12a about a second axial line AX2, which is a perpendicular line orthogonal to the first axial line AX1.

When the support body 12 is not tilted, as shown in FIG. 1, the second axial line AX2 coincides with the axial line PX and coincides with a central axial line of the ICP source unit 16 as a plasma source. On the other hand, when the support body 12 is tilted, as shown in FIG. 2, the second axial line AX2 is tilted with respect to the axial line PX and does not coincide with the central axial line of the ICP source unit 16 as a plasma source. That is, in the support body 12, only when the placement surface 12a is not tilted with respect to the horizontal plane, the perpendicular line passing through the center of the wafer W placed on the placement surface 12a (specifically, the center of the placement surface 12a) passes through the center of the ICP source unit 16 as a plasma source. Details of the support body 12 will be described later.

The exhaust system 20 is configured to be able to reduce a pressure of an internal space of the processing container 11 to, for example, a high vacuum. The exhaust system 20 includes, for example, an automatic pressure controller 20a, a turbo-molecular pump 20b, and a dry pump 20c. The turbo-molecular pump 20b is provided downstream of the automatic pressure controller 20a. A cryopump may be used instead of the turbo-molecular pump 20b. The dry pump 20c is directly connected to the internal space of the processing container 11 via a valve 20d. Further, the dry pump 20c is provided downstream of the turbo-molecular pump 20b via a valve 20e.

The exhaust system 20 including the automatic pressure controller 20a and the turbo-molecular pump 20b is attached to the bottom portion of the processing container 11 and is configured to exhaust the interior of the processing container 11 via the exhaust port 11b. Further, the exhaust system 20 including the automatic pressure controller 20a and the turbo-molecular pump 20b is provided directly below the support body 12. Therefore, in the tiltable pre-cleaning apparatus 10, a uniform flow of exhaust gas may be formed from the surrounding of the support body 12 toward the exhaust system 20. This makes it possible to achieve efficient exhaust. Further, it is possible to uniformly diffuse the plasma generated within the processing container 11.

In one embodiment, a shield 17 is detachably provided on an upper inner wall surface of the processing container 11, which defines the processing space S. A shield 26 is detachably provided on a lower inner wall surface of the processing container 11. Further, a shield 21 is detachably provided on a wall surface other than the placement surface 12a of the support body 12 and on an outer peripheral surface of the tilted shaft portion 50. The shields 17, 21 and 26 prevent by-products (hereinafter also referred to as “deposits”) generated by etching from adhering onto the interior of the processing container 11. The shields 17, 21 and 26 are constructed, for example, by blasting a surface of a base material made of aluminum or by additionally forming an aluminum sprayed film. The shield 26 may be divided into a plurality of parts so as to form, for example, a labyrinth structure, so that gas is guided to the exhaust system 20 via gaps included in the labyrinth structure. The shields 17, 21 and 26 may be replaced as appropriate.

An opening is provided in a ceiling portion of the processing container 11. The opening is closed by a dielectric window 19. The dielectric window 19 is a plate-shaped body made of quartz glass or ceramics.

The gas supplier 14 supplies a processing gas into the processing container 11 via flow paths 14a and 14b. Specifically, the flow paths 14a and 14b communicate with a plurality of (e.g., eight) gas holes 22 provided at equal intervals along a circumferential direction in a quartz member 18 (to be described later). The gas supplier 14 introduces the processing gas into the processing space S via the plurality of gas holes 22 arranged at equal intervals. As a result, the processing gas may be evenly introduced into the processing container 11 from the plurality of gas holes 22. This makes it possible to evenly generate plasma of the processing gas within the processing space S.

The gas supplier 14 may include at least one gas source and at least one flow rate controller. A flow rate of the processing gas from the gas source of the gas supplier 14 may be adjusted by the flow rate controller.

The ICP source unit 16 excites the processing gas supplied into the processing chamber 11. The ICP source unit 16 is provided, for example, on the dielectric window 19 in the ceiling portion of the processing container 11. Further, in one embodiment, the central axial line of the ICP source unit 16 coincides with the axial line PX. A space above the dielectric window 19 in which the ICP source unit 16 is provided is kept in an ambient atmosphere, and the internal space of the processing container 11 below the dielectric window 19 is kept in a depressurized atmosphere (vacuum atmosphere).

The ICP source unit 16 includes a radio-frequency antenna 53 and a shield member 52. The radio-frequency antenna 53 is covered with the shield member 52. The radio-frequency antenna 53 is made of a conductor such as copper, aluminum, or stainless steel, and extends in a spiral shape about the axial line PX. A radio-frequency power supply 51 is connected to the radio-frequency antenna 53. The radio-frequency power supply 51 supplies radio-frequency waves for plasma generation to the radio-frequency antenna 53.

When the radio-frequency waves of a predetermined frequency are supplied to the radio-frequency antenna 53 from the radio-frequency power supply 51 with a predetermined power, the radio-frequency waves pass through the dielectric window 19 and form an induced magnetic field inside the processing container 11. The processing gas introduced into the processing container 11 is plasmarized by the induced magnetic field. The frequency of the radio-frequency power supplied from the radio-frequency power supply 51 may be 13.56 MHz, 27 MHz, 40 MHz, or 60 MHz.

A shield plate 13 is arranged below the dielectric window 19 inside the processing container 11 and above positions of the flow paths 14a and 14b. The shield plate 13 is a thin quartz plate, and is provided near the dielectric window 19 to prevent by-products generated by etching from flying from the wafer W and adhering to the dielectric window 19.

The bias power supplier 62 is configured to supply a radio-frequency bias power to the support body 12 to draw ions into the wafer W. The radio-frequency power supply 51, the radio-frequency antenna 53, the dielectric window 19, and the gas supplier 14 function as a plasma generator that generates plasma in a plasma generation space U for generating plasma.

A slit plate 15 is provided between the dielectric window 19 and the support body 12 and below the shield plate 13. The slit plate 15 includes a quartz slit plate 15a in which a plurality of slits 15a1 are formed, and a quartz slit plate 15b arranged under the slit plate 15a and in which a plurality of slits 15b1 are formed.

An outer peripheral portion of the slit plate 15 is gripped by the inner wall of the processing container 11 to partition the plasma generation space U and the processing space S. The slit 15a1 is offset from the slit 15b1 in a direction opposite to a tilt direction of the placement surface 12a of the support body 12. The slit 15a1 and the slit 15b1 do not overlap in a plan view. “The tilt direction of the placement surface 12a of the support body 12” is a direction in which the line perpendicular to the tilted placement surface 12a is tilted with respect to the vertical direction.

By providing the slit plates 15a and 15b and the shield plate 13 as in the present embodiment and optimizing widths, positions, and the like of the slits 15a1 and 15b1, it is possible to maintain a function of preventing the adhesion of the by-products to the dielectric window 19 and achieve a high etching rate.

The inner wall surface of the processing container 11, which defines the plasma generation space U above the slit plate 15a, is covered with a cylindrical quartz member 18. An insulating property of the quartz member 18 may prevent the plasma generated in the plasma generation space U from being drawn into the grounded processing container 11 and disappearing.

The controller M is, for example, a computer including a processor such as a CPU, a memory, and the like, and is provided with a program storage (not shown). The program storage stores a program incorporating commands for controlling each part of the tiltable pre-cleaning apparatus 10 to implement wafer processing (to be described later). The program may be recorded on a computer-readable storage medium H and may be installed in the controller M from the storage medium H. The storage medium H may be transitory or non-transitory.

### <Support Body 12>

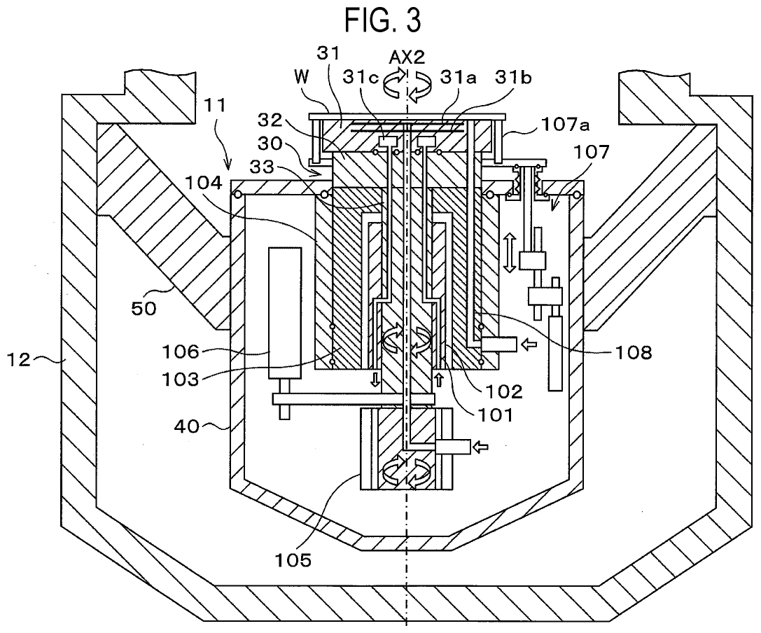

Next, the support body 12 will be further described using FIG. 3 with reference to FIGS. 1 and 2. FIG. 3 is a diagram showing an example of an internal structure of a container, which will be described later.

The support body 12 is configured to be able to tilt the placement surface 12a with respect to a horizontal plane while supporting the wafer W on the placement surface 12a. Further, the support body 12 rotatably supports the wafer W as described above. As shown in FIGS. 1 and 2, the support body 12 includes a holder 30 and a container 40, and is connected to the tilted shaft portion 50.

The holder 30 is a mechanism that holds the wafer W and rotates the wafer W about the second axial line AX2 by rotating about the second axial line AX2. As shown in FIG. 3, the holder 30 includes the electrostatic chuck 31, a lower electrode 32, and a rotary shaft portion 33.

The electrostatic chuck 31 holds the wafer W on its upper surface, that is, the placement surface 12a. The electrostatic chuck 31 has a substantially disk-like shape centered on the second axial line AX2 and includes an electrode 31a. The electrostatic chuck 31 electrostatically attracts the wafer W placed on the placement surface 12a by virtue of an electrostatic force generated by applying a voltage to the electrode 31a. A heat transfer gas such as a He gas or the like may be supplied between the electrostatic chuck 31 and the wafer W. Further, a heater 31b for heating the wafer W may be built in the electrostatic chuck 31. Further, a flow path 32c of a temperature-adjusting fluid (specifically, for example, a low-temperature coolant for cooling the wafer W) for adjusting a temperature of the wafer W may be formed in the electrostatic chuck 31. The electrostatic chuck 31 is provided on the lower electrode 32.

The lower electrode 32 has a substantially disk-like shape centered on the second axial line AX2. The lower electrode 32 is made of a conductor such as aluminum or the like. The lower electrode 32 is electrically connected to the bias power supplier 62. The flow path 32c through which the temperature-adjusting fluid flows may be provided in the lower electrode 32 instead of or in addition to the electrostatic chuck 31.

The rotary shaft portion 33 has a substantially cylindrical shape and is connected to the center of a lower surface of the lower electrode 32. The central axial line of the rotary shaft portion 33 coincides with the second axial line AX2. By applying a rotational force to the rotary shaft portion 33, the holder rotates.

The holder 30 configured as above constitutes the support body 12 together with the container 40. A through-hole through which the rotary shaft portion 33 passes is formed in the center of the top wall of the container 40. A magnetic fluid seal portion 104 is provided between the container 40 and the rotary shaft portion 33. The magnetic fluid seal portion 104 hermetically seals the internal space of the container 40, that is, the internal space of the support body 12. The magnetic fluid seal portion 104 maintains the internal space of the container 40, that is, the internal space of the support body 12 in an ambient atmosphere, and isolates the internal space from the processing space S kept in a vacuum state.

Inside the container 40, a rotary joint (rotary coolant joint) 102 for supplying the temperature-adjusting fluid to the fluid flow path 101 is arranged around the outer periphery of the rotary shaft portion 33. The temperature-adjusting fluid supplied to the fluid flow path 101 is supplied to the flow path 31c within the electrostatic chuck 31. A hollow cylindrical lower electrode holder 103 is arranged around the outer periphery of the rotary joint 102. The aforementioned magnetic fluid seal portion 104 is arranged on the outer periphery of the lower electrode holder 103.

A slip ring 105 for supplying electric power to the electrode 31a and the heater 31b of the electrostatic chuck 31 and supplying bias electric power to the lower electrode 32 is arranged below the rotary joint 102 inside the container 40. In a space between the outer periphery of the magnetic fluid seal portion 104 and the inner wall of the container 40, a rotation motor 106 for rotating the rotary shaft portion 33 and a lift mechanism 107 for raising and lowering lift pins 107a to raise and lower the wafer W with respect to the holder 30 are arranged. Further, a gas line 108 for supplying the heat transfer gas between the electrostatic chuck 31 and the wafer W may be provided in the rotary shaft portion 33 or the lower electrode holder 103.

The rotation motor 106 generates a drive force for rotating the rotary shaft portion 33. When the rotary shaft portion 33 is rotated about the second axial line AX2 by the rotation motor 106, the holder 30 and the wafer W held by the holder 30 are rotated about the second axial line AX2. A rotational speed of the holder 30 may fall within a range of, for example, 10 rpm to 60 rpm.

Further, as shown in FIG. 1, an opening is formed in the container 40 along a line parallel to and offset from the first axial line AX1. An inner end of the tilted shaft portion 50 is fitted into this opening. An outer portion of the tilted shaft portion 50 reaches the processing container 11, and the end portion thereof extends to the outside of the processing container 11. Further, the outer portion of the tilted shaft portion 50 extends along the first axial line AX1.

The driver 24 pivotally supports one outer end portion of the tilted shaft portion 50. When the tilted shaft portion 50 is rotated about the first axial line AX1 by the driver 24, the container 40 and the support body 12 are rotated about the first axial line AX1. As a result, the support body 12 is tilted. Specifically, the placement surface 12a is tilted with respect to the horizontal plane. For example, the placement surface 12a may be tilted such that the second axial line AX2 forms an angle in a range of 0 degrees to 90 degrees with respect to the axial line PX.

As described above, in one embodiment, the height of the first axial line AX1 is equal to the height of the wafer W on the placement surface 12a (specifically, the height of the upper surface of the wafer W) when the support body 12 is not tilted. In this case, the center of the wafer W on the placement surface 12a is located on the axial line PX regardless of the tilt angle of the support body 12. Thus, it is possible to provide a margin for process controllability.

Various electrical system wirings, heat transfer gas pipes, and coolant pipes may pass through an inner hole of the tilted shaft portion 50. These wirings and pipes are connected to the rotary shaft portion 33. A wiring for supplying electric power to the rotation motor 106 may also pass through the inner hole of the tilted shaft portion 50. The wiring for the rotation motor 106 is drawn out to the outside of the processing container 11 via, for example, the inner hole of the tilted shaft portion 50, and is connected to a motor power supply provided outside the processing container 11.

### <Etching Process>

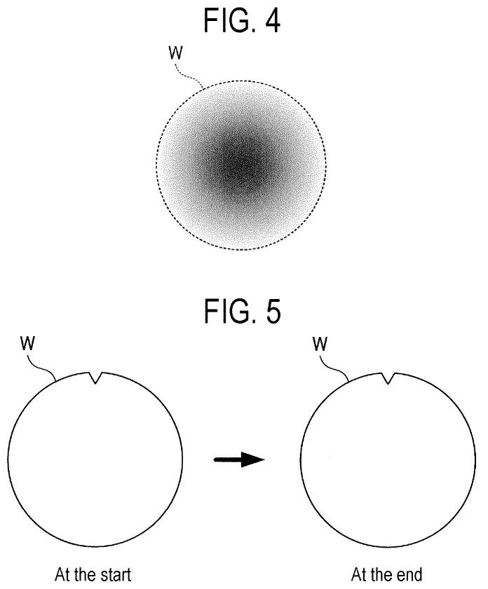

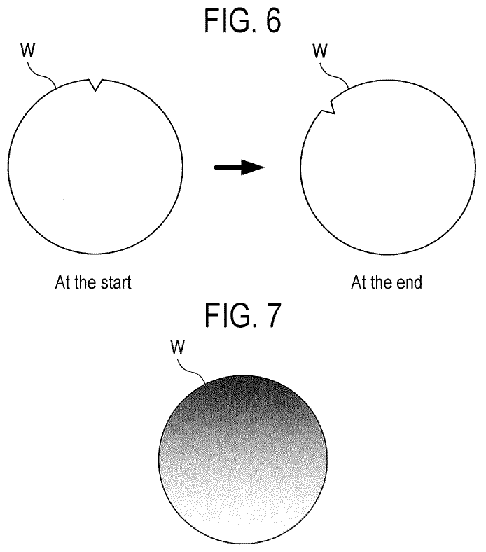

Next, an example of an etching process using the tiltable pre-cleaning apparatus 10 will be described with reference to FIGS. 4 to 6. FIG. 4 is a diagram showing an example of a plasma density distribution on the upper surface of the wafer W placed on the placement surface 12a, in which diagram the higher the plasma density, the darker the color. FIGS. 5 and 6 are diagrams showing examples of an orientation of the wafer W at the start and end of the plasma etching. The following operations are performed under the control of the controller M.

### (Step S1: Loading)

First, the wafer W is loaded into the processing container 11.

Specifically, the gate valve for a loading/unloading port (not shown) provided in the processing container 11 is opened, and a transfer mechanism (not shown) that holds the wafer W is inserted from a transfer chamber (not shown) in a depressurized atmosphere adjacent to the processing container 11 into the processing container 11 via the loading/unloading port. Subsequently, the lift pins 107a are raised, and the wafer W is transferred from the transfer mechanism to the lift pins 107a. Thereafter, the transfer mechanism is withdrawn from the processing container 11, and the gate valve is closed. At the same time, the lift pins 107a are lowered, and the wafer W is placed on the horizontal placement surface 12a of the support body 12. Thereafter, a voltage is applied to the electrode 31a of the electrostatic chuck 31 to generate an electrostatic attraction force. By the electrostatic attraction force, the wafer W is held on the placement surface 12a.

### (Step S2: Tilting and Rotating)

Subsequently, the support body 12 is tilted, and the wafer W is tilted and rotated. Specifically, the placement surface 12a on which the wafer W is placed is tilted with respect to the horizontal plane, and the wafer W is rotated about a perpendicular line passing through the center of the wafer W placed on the placement surface 12a, that is, the second axial line AX2.

More specifically, the support body 12 is rotated about the first axial line AX1, and the placement surface 12a on which the wafer W is placed is tilted with respect to the horizontal plane so as to have a predetermined tilt angle. At the same time, the support body 12 is rotated about the second axial line AX2, and the wafer W placed on the placement surface 12a is rotated at a predetermined rotational speed.

### (Step S3: Plasma Etching)

Thereafter, the plasma etching is performed on the wafer W while the tilted wafer W is being rotated.

Specifically, the processing gas is supplied to the processing space S from the gas supplier 14. Further, plasma generation is started. More specifically, the supply of the radio-frequency waves for plasma generation from the radio-frequency power supply 51 to the radio-frequency antenna 53 of the ICP source unit 16 is started. As a result, plasma of the processing gas is generated inside the processing chamber 11, and the plasma etching is started.

When a predetermined period of etching time has elapsed after the supply of the radio-frequency waves for plasma generation is started, that is, after the plasma etching is started, the supply of the radio-frequency waves is stopped, that is, the plasma etching is stopped. During the plasma etching, the radio-frequency bias power may be supplied to the support body 12 from the bias power supplier 62.

During the plasma etching, the total number of rotations of the wafer W (specifically, the total number of rotations about the second axial line AX2 of the wafer W placed on the placement surface 12a) is controlled to a predetermined value. In one embodiment, the total number of rotations is controlled to become a natural number. Specifically, the wafer W is controlled to rotate during the plasma etching at a rotational speed determined in a predetermined range based on a predetermined etching time, so that the total number of rotations becomes the natural number. In other words, the wafer W is controlled to rotate during the plasma etching at a rotational speed determined so as to satisfy the following (A) and (B) based on the predetermined etching time:
(A) the total number of rotations of the wafer W is the natural number; and
(B) the rotational speed of the wafer W is in a predetermined range (e.g., 10 rpm to 60 rpm).

That is, as shown in FIG. 5, the orientation of the wafer W is controlled to remain unchanged at the start and end of the plasma etching.

Further, the rotational speed V of the wafer W during the plasma etching is constant and is, for example, determined in advance. The etching time T is predetermined according to a processing recipe or the like stored in a storage (not shown).

The reason why such controls is performed as described above will be described.

First, an example of why the plasma etching is performed on the wafer W while the tilted wafer W is being rotated will be described. In the configuration in which the perpendicular line passing through the center of the wafer W placed on the placement surface 12a passes through the center of the ICP source unit 16 only when the wafer W is not tilted, when the wafer W is not tilted, as shown in FIG. 4, the plasma density distribution on the upper surface of the wafer W does not vary in the circumferential direction of the wafer W, but may vary in a radial direction of the wafer W. In this case, even if the wafer W is rotated about the second axial line AX2, it is difficult to suppress variations in plasma etching results in the wafer plane, which are caused by the variations in the plasma density distribution on the upper surface of the wafer W. On the other hand, in the above case, when the wafer W is tilted, the plasma density distribution on the upper surface of the wafer W also varies in the circumferential direction of the wafer W. Therefore, by rotating the wafer W about the second axial line AX2, it is possible to suppress the variations in plasma etching results in the wafer plane.

However, in the case where the plasma etching is performed on the wafer W while the tilted wafer W is being rotated, when the wafer W is rotated during the plasma etching at a rotational speed determined without considering the etching time, as shown in FIG. 6, the orientation of the wafer W may be changed between the start and end of the plasma etching. In this case, a time required for each region of the surface of the wafer W to pass through a region having high etching strength in the processing space S and a time required for each region of the surface of the wafer W to pass through a region having low etching strength in the processing space S may differ between the regions. This may result in variations in the plasma etching results in the plane of the wafer W.

In contrast, the orientation of the wafer W is controlled to remain unchanged at the start and end of the plasma etching. Therefore, the time required for each region of the surface of the wafer W to pass through the region having high etching strength in the processing space S and the time required for each region of the surface of the wafer W to pass through the region having low etching strength in the processing space S may be made approximately equal between the regions. This makes it possible to suppress the variations in the plasma etching results in the plane of the wafer W.

### (Step S4: Horizontal Position Return and Rotation Stop)

After step S3, the support body 12 is returned to be in the horizontal state, and the rotation of the wafer W is stopped. Specifically, the support body 12 is rotated about the first axial line AX1, the placement surface 12a on which the wafer W is placed is returned to be in the horizontal state, and the rotation of the wafer W about the second axial line AX2 is stopped.

### (Step S5: Unloading)

Then, the wafer W is unloaded from the processing container 11.

Specifically, the wafer W is unloaded from the processing container 11 in the reverse procedure of step S1. Thus, a series of etching processes are completed.

### Main Effects of the Present Embodiment

In the present embodiment, as described above, only when the placement surface 12a is not tilted with respect to the horizontal plane, the perpendicular line passing through the center of the wafer W placed on the placement surface 12a, that is, the second axial line AX2, passes through the center of the ICP source unit 16. Further, during the plasma etching, the placement surface 12a is controlled to be tilted with respect to the horizontal plane and the wafer W placed on the placement surface 12a is controlled to rotate about the second axial line AX2. Then, the total number of rotations of the wafer W placed on the placement surface 12a about the second axial line AX2 during the plasma etching is controlled to become a natural number. That is, the orientation of the wafer W is controlled to remain unchanged at the start and end of the plasma etching. Therefore, it is possible to suppress the variations in plasma etching results in the plane of the wafer W.

Further, in the present embodiment, the total number of rotations of the wafer W during the plasma etching is controlled to become the natural number. That is, the wafer W is rotated during the plasma etching at a rotational speed calculated and determined so that the total number of rotations becomes the natural number. Therefore, as compared to a case where the total number of rotations is not an integer, the rotational speed of the wafer W during the plasma etching may be determined by a relatively simple calculation.

### Modification

FIG. 7 is a diagram for explaining another example of the total number of rotations of the wafer W during the plasma etching, and shows an in-plane distribution of the total amount of etching during the plasma etching. Further, in FIG. 7, the larger the total amount of etching, the darker the color.

Even if the total number of rotations of the wafer W during the plasma etching is controlled to become the natural number as in the above example, that is, even if the orientation of the wafer W is controlled to remain unchanged at the start and end of the plasma etching, it may not be possible to sufficiently reduce the variations in the plasma etching results in the plane of the wafer W. Specifically, for example, at the start and end of the plasma etching, the total amount of etching may be large on the side of the wafer W closer to the ICP source unit 16 (the right side in FIG. 2 and the upper side in FIG. 7), and the total amount of etching may be small on the side of the wafer W far from the ICP source unit 16 (the left side in FIG. 2 and the lower side in FIG. 7).

In this case, the total number of rotations of the wafer W during the plasma etching may be controlled to become the sum of a natural number and a predetermined decimal number. For example, the total number of rotations of the wafer W during the plasma etching may be as follows. That is, when the total number of rotations of the wafer W during the plasma etching is controlled to be the natural number, a portion where the total amount of etching is small may be located at a portion where the total amount of etching is large at the end of the plasma etching. Specifically, in the case of the example shown in FIG. 7, the portion of the wafer W far from the ICP source unit 16 at the start of the plasma etching, in which the total amount of etching is small when the total number of rotations of the wafer W during the plasma etching is controlled to be the natural number, may be located at a position far from the ICP source unit 16, in which the total amount of etching is large at the end of the plasma etching.

The predetermined decimal number is, for example, 0.5, and is determined in advance by a preliminary test or the like. By performing the above-described controls in this manner, it is possible to further suppress the variations in plasma etching results in the plane of the wafer W.

According to the present disclosure in some embodiments, it is possible to improve uniformity of plasma etching results in a substrate plane.

The embodiments disclosed herein should be considered to be exemplary in all respects and not limitative. The embodiments described above may be omitted, replaced, or modified in various forms without departing from the scope and spirit of the appended claims. For example, the constituent elements of the above embodiments may be combined arbitrarily. This arbitrary combination naturally provides the actions and effects of the respective constituent elements of the combination, and other actions and effects that would be apparent to those skilled in the art from the description of this specification.

Further, the effects described in this specification are merely explanatory or exemplary, and are not limitative. That is, the technique according to the present disclosure may have other effects that would be obvious to those skilled in the art from the description of this specification, in addition to or in place of the above-mentioned effects.

The following configuration examples also belong to the technical scope of the present disclosure.

(1) A plasma etching apparatus includes: a chamber; a support body provided inside the chamber and configured to hold a substrate; a plasma generator including a plasma source and configured to generate plasma inside the chamber; and a controller, wherein the support body has a placement surface on which the substrate is placed, and is configured to rotate the substrate about a perpendicular line passing through a center of an upper surface of the substrate placed on the placement surface, and the support body is configured such that the placement surface is tilted with respect to a horizontal plane, the perpendicular line passes through a center of the plasma source only when the placement surface is not tilted with respect to the horizontal plane, and the controller performs a first control so that during a plasma etching, the placement surface is tilted with respect to the horizontal plane and the substrate placed on the placement surface is rotated about the perpendicular line, and a second control so that a total number of the rotations of the substrate placed on the placement surface about the perpendicular line during the plasma etching becomes a predetermined value.

(2) In the plasma etching apparatus of (1) above, the predetermined value is a natural number.

(3) In the plasma etching apparatus of (1) or (2) above, the controller performs a third control so that the substrate placed on the placement surface is rotated at a rotational speed determined in a predetermined range based on a time required for the plasma etching so that the total number of the rotations becomes the predetermined value.

(4) A plasma etching method of etching a substrate by plasma using a plasma etching apparatus including a chamber; a support body provided inside the chamber and configured to hold the substrate; and a plasma generator including a plasma source and configured to generate the plasma inside the chamber, wherein the support body has a placement surface on which the substrate is placed, and is configured to rotate the substrate about a perpendicular line passing through a center of an upper surface of the substrate placed on the placement surface, and the support body is configured such that the placement surface is tilted with respect to a horizontal plane, the perpendicular line passes through a center of the plasma source only when the placement surface is not tilted with respect to the horizontal plane. The plasma etching method includes: performing a plasma etching while rotating the substrate placed on the placement surface about the perpendicular line in a state in which the placement surface is tilted with respect to the horizontal plane; and rotating the substrate placed on the placement surface so that a total number of the rotating the substrate placed on the placement surface about the perpendicular line during the plasma etching becomes a predetermined value.

What is claimed is:

1. A plasma etching apparatus, comprising:
a chamber;
a support body provided inside the chamber and configured to hold a substrate;
a plasma generator including a plasma source and configured to generate plasma inside the chamber; and
a controller,
wherein the support body has a placement surface on which the substrate is placed, and is configured to rotate the substrate about a perpendicular line passing through a center of an upper surface of the substrate placed on the placement surface, and the support body is configured such that the placement surface is tilted with respect to a horizontal plane, the perpendicular line passes through a center of the plasma source only when the placement surface is not tilted with respect to the horizontal plane, and
wherein the controller performs a first control so that during a plasma etching, the placement surface is tilted with respect to the horizontal plane and the substrate placed on the placement surface is rotated about the perpendicular line, and a second control so that a total number of the rotations of the substrate placed on the placement surface about the perpendicular line during the plasma etching becomes a predetermined value.

2. The plasma etching apparatus of claim 1, wherein the predetermined value is a natural number.

3. The plasma etching apparatus of claim 2, wherein the controller performs a third control so that the substrate placed on the placement surface is rotated at a rotational speed determined in a predetermined range based on a time required for the plasma etching so that the total number of the rotations becomes the predetermined value.

4. The plasma etching apparatus of claim 1, wherein the controller performs a third control so that the substrate placed on the placement surface is rotated at a rotational speed determined in a predetermined range based on a time required for the plasma etching so that the total number of the rotations becomes the predetermined value.

5. A plasma etching method of etching a substrate by plasma using a plasma etching apparatus,
wherein the plasma etching apparatus includes:
a chamber;
a support body provided inside the chamber and configured to hold the substrate; and
a plasma generator including a plasma source and configured to generate the plasma inside the chamber,
wherein the support body has a placement surface on which the substrate is placed, and is configured to rotate the substrate about a perpendicular line passing through a center of an upper surface of the substrate placed on the placement surface, and the support body is configured such that the placement surface is tilted with respect to a horizontal plane, the perpendicular line passes through a center of the plasma source only when the placement surface is not tilted with respect to the horizontal plane,
the plasma etching method comprises:
performing a plasma etching while rotating the substrate placed on the placement surface about the perpendicular line in a state in which the placement surface is tilted with respect to the horizontal plane; and
rotating the substrate placed on the placement surface so that a total number of the rotating the substrate placed on the placement surface about the perpendicular line during the plasma etching becomes a predetermined value.
